(19) United States
(12) Patent Application Publication
(10) Pub. No.: US 2007/0152348 A1
(43) Pub. Date: Jul. 5, 2007

(54) ARRAY CIRCUIT SUBSTRATE AND WIRE BONDING PROCESS USING THE SAME

(76) Inventors: Ying-Chih Chen, Kaohsiung County (TW); Yun-Hsiang Tien, Kaohsiung County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/309,680

(22) Filed: Sep. 11, 2006

(30) Foreign Application Priority Data
Jan. 4, 2006 (TW) 95100316

(51) Int. Cl. H01L 23/48

(52) U.S. Cl. 257/786

(57) ABSTRACT

An array circuit substrate including a plurality of substrate units, a plurality of non-stick test circuits, and a plurality of etching windows is provided. Each of the substrate units has a plurality of wire-bond pads and a plurality of plated wires. One of the plated wires is connected to one of the corresponding wire-bond pads, and at least one of the plated wires is a test wire. The non-stick test circuits are respectively disposed between two adjacent substrate units. Each test wire is connected to a test point through the non-stick test circuits. The etching windows are located on the substrate units. The plated wires are respectively cut by the etching windows except the test wires. Furthermore, the non-stick test circuits are not cut by the etching windows.

### CROSS-REFERENCE TO RELATED APPLICATION

This application claims the priority benefit of Taiwan application serial no. 95100316, filed on Jan. 4, 2006. All disclosure of the Taiwan application is incorporated herein by reference.

### BACKGROUND OF THE INVENTION

1. Field of the Invention

The present invention relates to an array circuit substrate, and more particularly, to an array circuit substrate and wire bonding process suitable for a non-stick test.

2. Description of Related Art

In the semiconductor manufacturing industry, the production of integrated circuit can be roughly divided into three major stages: the integrated circuit (IC) designing, integrated circuit (IC) processing and integrated circuit (IC) packaging. In the IC processing stage, dies are formed after going through processes such as wafer fabrication, integrated circuit processing and wafer sawing. The wafer has an active surface, which generally means the wafer surface where active devices are disposed. After forming integrated circuits on the wafer, a plurality of bonding pads is disposed on the active surface of the wafer so that the die sawn from the wafer can be electrically connected to an external carrier through these bonding pads. The carrier can be a lead frame or a package substrate, for example. The die is joined to the carrier by performing a wire bonding or flip-chip bonding process so that the bonding pads on the die are electrically connected to the respective contacts on the carrier to form a chip package.

In the wire bonding technique, after attaching the die to the package substrate through epoxy, a thermal compression bonding or ultrasound bonding method is used to join the respective ends of a bonding wire to the die and the package substrate. Hence, the die and the package substrate are electrically connected. In the foregoing wire bonding process, a good bonding of the ends of a bonding wire to the bonding pad of the die and the contact on the package substrate is related to the performance of the chip package. That is why a non-stick test is necessary after the wire bonding process.

FIG. 1 is a top view of a conventional array circuit substrate. The conventional array circuit substrate 100 includes a plurality of substrate units 110, a plurality of first plated wires 120 (non-stick testing circuits) and a plurality of etching windows 130. A chip 10 (only one is shown) is disposed on the substrate unit 110 and is electrically connected to wire bonding pads 112 of the substrate unit 110 through bonding wires 12. Adjacent substrate units 110 are separated from each other through grid-like first plated wires 120. Furthermore, each of the substrate units 110 has a plurality of second plated wires 114 for electrically connecting the respective wire bonding pads 112 to the adjacent first plated wires 120. As a result, a testing signal is able to transmit from a test point 122 on the first plated wires 120 to the second plated wires 114 and then transmit from there to a connected wire bonding pad 112 and corresponding bonding pad on the chip 10. Accordingly, when the testing signal reports back to the non-stick testing system, the system can determine if the bonding wire 12 is properly bonded to the bonding pad on the chip 10.

However, as shown in FIG. 1, before the wire bonding process, all of the second plated wires 114 are cut by the etching windows 130, and some of the first plated wires 120 are cut by the etching windows 132 to open the closed circuit constituted of the first plated wires 120 and the second plated wires 114 after the plating process, so that the non-stick testing mechanism will be completely written off. In other words, testing signal can no longer be transmitted back to the testing contact 122 through the intact first plated wires 120 and the intact second plated wires 114. If a visual inspection instead of a testing system is used to determine whether the non-stick phenomenon has occurred, because the accuracy of the visual inspection is so low and that the visual inspection must be carried out after the wire bonding process, non-stick problem may not be found until it is too late.

### SUMMARY OF THE INVENTION

Accordingly, at least one objective of the present invention is to provide an array circuit substrate for increasing the accuracy of non-stick test and promptly finding non-stick problem in the wire bonding process. The other objective of the present invention is to provide a wire bonding process for checking the bonding wire is connected to the bonding pad or not.

To achieve these and other advantages and in accordance with the purpose of the invention, as embodied and broadly described herein, the invention provides an array circuit substrate. The array circuit substrate includes a plurality of substrate units, a plurality of non-stick test wires, and a plurality of etching windows. Each of the substrate units has a plurality of wire-bond pads and a plurality of plated wires. One of the plated wires is connected to one of the corresponding wire-bond pads, and at least one of the plated wires is a test wire. The non-stick test wires are respectively disposed between two adjacent substrate units. Each test wire is connected to a test contact through the non-stick test wires. The etching windows are located in the substrate units. The plated wires are cut by the etching windows except the test wires. Furthermore, the non-stick test wires are not cut by the etching windows.

In one embodiment of the present invention, a wire bonder bonds the first end of a first bonding wire to one of the bonding pads on the chip.

In one embodiment of the present invention, a first end of the first bonding wire is bonded to one of bonding pads on a chip. In addition, a second end of the first bonding wire is bonded to the wire bonding pad that is electrically connected to the test wire.

In one embodiment of the present invention, the foregoing etching windows are formed by optical etching.

In one embodiment of the present invention, the foregoing etching windows are formed by wet etching or dry etching.

In one embodiment of the present invention, the foregoing etching windows are substantially in parallel to the adjacent non-stick test wires.

In one embodiment of the present invention, the width of the foregoing etching windows is about 100˜200 μm.

In one embodiment of the present invention, the foregoing etching windows separate from their adjacent non-stick test wires by about 50 μm.

A wire bonding process is provided by providing an array substrate, which having a plurality of wire bonding pads, a plurality of plated wires and a plurality of non-stick test circuits, and each of the plated wires are connected one of the corresponding wire bonding pads to the adjacent non-stick test circuits, wherein at least one of the plated wires is a test wire. Then, a plurality of etching windows are formed to cut the plated wires expect the test wire. Then, bonding a first end of a first bonding wire to one of bonding pads on a chip; and bonding a second end of the first bonding wire to a first wire bonding pad, which electrically connected to the test wire. Then, bonding a first end of a second bonding wire to a second bonding pad of the chip. Performing a non-stick test to check whether the first and second bonding wires are in good bonding condition or not, if yes, a current signal is received by a tester, if not, a current signal is not received by the tester or the received current signal is smaller than a predefined value. Then, bonding a second end of the second bonding wire to a second wire bonding pad, and cutting the second bonding wire out from a wire bonder. Performing the non-stick test to check whether the second bonding wire is connected to the second wire bonding pad or not, if yes, a current signal is not received by the tester, if not, a current signal is received by the tester. Then, repeating the wire bonding steps and the non-stick test until the connection between the bonding pads and the wire bonding pads are completed.

Accordingly, the array circuit substrate of the present invention serves as a medium for testing the flow of current in a non-stick test. Therefore, the array circuit substrate of the present invention is able to increase the accuracy of the non-stick test. Furthermore, because the array circuit substrate in the present invention can carry out the non-stick test in tandem with the wire bonding process, any non-stick problem can be found through the non-stick test just after the wire bonding process immediately.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a top view of a conventional array circuit substrate.

FIG. 2 is a top view of an array circuit substrate according to one embodiment of the present invention.

FIG. 3 is a diagram showing a wire bonding process and a non-stick test performed on a chip in the array circuit substrate shown in FIG. 2.

FIG. 4 is a diagram showing a subsequent wire bonding process and a non-stick process performed on the chip in the array circuit substrate shown in FIG. 3.

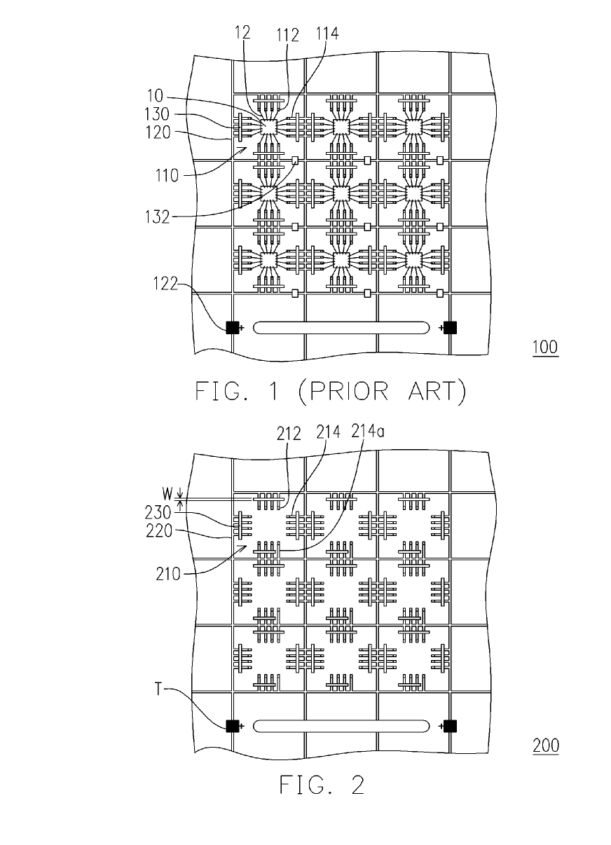

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

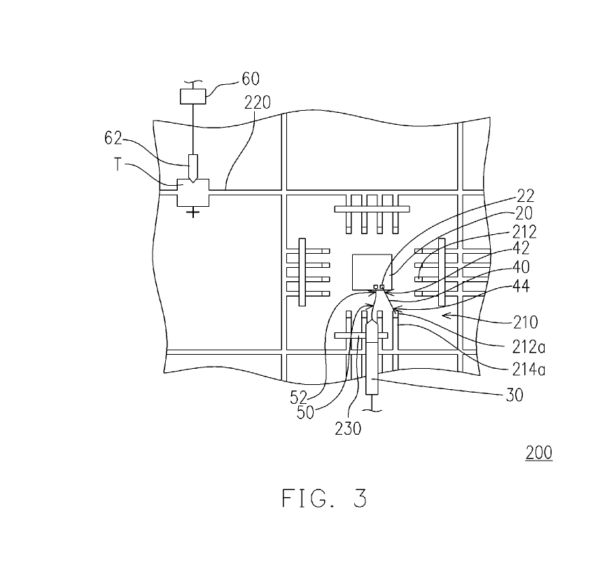

FIG. 2 is a top view of an array circuit substrate according to one embodiment of the present invention. The array circuit substrate 200 in the present invention includes a plurality of substrate units 210, a plurality of non-stick test wires 220 and a plurality of etching windows 230. Each of the substrate units 210 includes a plurality of wire bonding pads 212 and a plurality of plated wires 214. One of these plated wires 214 is connected to one of the corresponding wire bonding pads 212. Furthermore, at least one of the plated wires (hereinafter “a test wire 214a”) in each substrate unit 210 is retained as an uncut wire, that is, not cut by the etching window 230. Hence, the uncut wire is able to electrically connect with an adjacent non-stick test circuit 220.

The non-stick test circuits 220 and the plated wires 214 are conductive wires laid out for conventional plating process. Therefore, after the plating process, using the conductive wires laid out for the plating process to serve as the non-stick test circuits 220 and the test wires 214a eliminates the need to dispose wires on the array circuit substrate 200. The non-stick test circuits 220 are respectively disposed between adjacent substrate units 210. Each non-stick circuit connects the test wire 214a to a test contact T and forms a complete testing circuit. It should be noted that, after the plating process, the plated wires 214 are respectively cut by the etching windows 230 in each of the substrate units 210 except the test wires 214a, as well as the non-stick test circuits 220 are not cut by the etching windows 230. In the present embodiment, the etching windows 230 are formed, for example, by performing optical etching, wet etching or dry etching. Aside from the test wires 214a, the etching windows 230 break open the circuit connections between the plated wires 214 and the non-stick test circuits 220.

Position-wise, the etching windows 230 in the present embodiment are disposed substantially in parallel to the adjacent non-stick test circuits 220 and separated from the adjacent non-stick test circuits 220 by about 50 μm. Dimension-wise, the width W of the etching windows 230 in the present embodiment is between about 100˜200 μm. Moreover, the etching windows 230 serve only to break open the circuit connections between the plated wires 214 and the non-stick test circuits 220 except the test wire 214a. Therefore, the location and external appearance of the etching windows 230 may be modified according to the requirements of the designer as long as the aforementioned function is unaffected. In other words, the present embodiment only serves as an example and should not be used to limit the scope of the present invention.

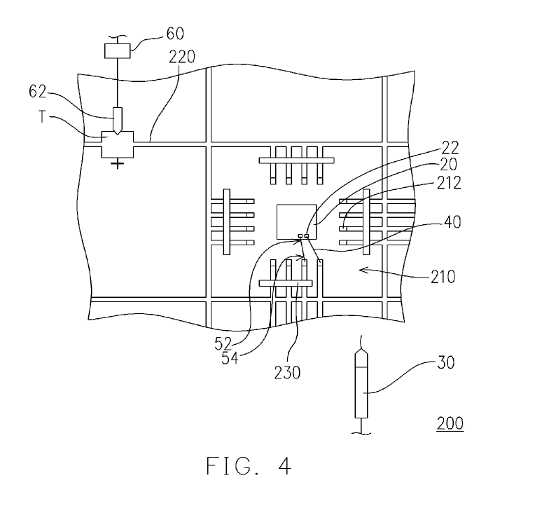

In the following, a wire bonding process and a non-stick test on the array circuit substrate 200 and the chip 20 in the present embodiment are explained in more detail. FIG. 3 is a diagram showing a wire bonding process and a non-stick test performed on a chip in the array circuit substrate shown in FIG. 2. To simplify the explanation, a single chip 20 attached to a substrate unit 210 is drawn in FIG. 3. In the present embodiment, the wire bonding process includes the following steps. First, a wire bonder 30 bonds a first end 42 of a first bonding wire 40 to one of the bonding pads 22. To prevent the first bonding wire 40 from contacting the peripheral region of the chip 20, the wire bonder 30 pulls out an arc and bonds a second end 44 of the first bonding wire 40 to a wire bonding pad 212a with electrical connection to the test wire 214a. Afterwards, the wire bonder 30 bonds a first end 52 of a second bonding wire 50 to the next bonding pad 22 on the chip 20.

In the meantime, the non-stick test is also executed. Because the wire bonder 30 is electrically connected to a tester 60 with a probe pin 62 and the probe pin 62 is electrically connected to the test point T, therefore, if the first bonding wire 40 and the second bonding wire 50 formed in the foregoing wire bonding process are in good bonding condition, the probe pin 62, the test point T in contact with the probe pin 62, the non-stick test circuit 220 connecting between the test point T and the test wire 214a, the test wire 214a, the wire bonding pad 212a, the first bonding wire 40, the chip 20, the second bonding wire 50 and the wire bonder 30 will form a closed circuit. If, at this moment, a current flows from the wire bonder 30 toward the second bonding wire 50, the tester 60 is able to receive this current signal. On the contrary, if the tester 60 does not pick up any current signal or the received current signal is smaller than a predefined value, this indicates that the bonding condition of the first bonding wire 40 or the second bonding wire 50 is not good.

Afterwards, a subsequent wire bonding process is carried out. FIG. 4 is a diagram showing a subsequent wire bonding process and a non-stick process performed on the chip in the array circuit substrate shown in FIG. 3. The wire bonder 30 bonds a second end 54 of the second bonding wire 50 to one of the remaining wire bonding pads 212 on the substrate unit 210 and severs the connection between the second end 54 of the second bonding wire 50 and the wire bonder 30.

Next, the non-stick test is executed. Because the wire bonder 30 and the second bonding wire 50 are no longer connected, the foregoing closed circuit becomes an open circuit. At this moment, if a current flows from the wire bonder 30 toward the second bonding wire 50, the tester 60 will not pick up this current signal. On the contrary, if the tester 60 still manages to receive a current signal, this indicates that the connection between the second end 54 of the second bonding wire 50 and the wire bonder 30 has not been completely severed. Furthermore, the wire bonder 30 may pull the second end 54 of the second bonding wire 50 due to an incomplete severance of the second end 54 of the second bonding wire 50 and lead to a poor bonding connection.

Then, the foregoing steps are repeated until the wire bonding process and non-stick test for connecting between the bonding pads 22 on the chip 20 and the wire bonding pads 212 on the substrate unit 210 are completed. Finally, the array package substrate is sawn along the conductive wire (that is, the grid-like non-stick test circuits 220) laid down by the conventional plating process using a cutter to cut through the connected test wires and non-stick test circuits and produce a plurality of independent substrate units 210. Each of the wire-bonded chips 20 and the structures of the substrate units 210 is subsequently encapsulated and then solder balls are implanted to form different types of chip packages. Since these processes should be familiar, a detailed description is not provided.

In summary, the array circuit substrate in the present invention has at least the following advantages:

1. Since the array circuit substrate in the present invention provides a complete test circuit to serve as a medium for the flow of a test current in the non-stick test, the failure of the non-stick test due to the cutting of the test circuit by an etching window is prevented.

2. Because a non-stick testing of the array circuit substrate of the present invention is carried out immediately after the wire bonding process, non-stick problem is found immediately compared with the conventional visual non-stick technique.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An array circuit substrate, comprising:
a plurality of substrate units, each having a plurality of wire bonding pads and a plurality of plated wires and each of the plated wires are connected to one of the corresponding wire bonding pads, wherein at least one of the plated wires is a test wire;
a plurality of non-stick test circuits, respectively disposed between two adjacent substrate units and connected the test wire to a test point; and
a plurality of etching windows, located within the substrate units, wherein the plated wires are cut by the etching windows except the test wire and the non-stick test circuits are not cut by the etching windows.

2. The array circuit substrate of claim 1, wherein a first end of a first bonding wire is bonded to one of bonding pads on a chip.

3. The array circuit substrate of claim 2, wherein a second end of the first bonding wire is bonded to the wire bonding pad, which electrically connected to the test wire.

4. The array circuit substrate of claim 1, wherein the etching windows are formed by optical etching.

5. The array circuit substrate of claim 1, wherein the etching windows are formed by wet etching or dry etching.

6. The array circuit substrate of claim 1, wherein the etching windows are substantially parallel to the adjacent non-stick test circuits.

7. The array circuit substrate of claim 1, wherein the width of the etching windows is about 100˜200 μm.

8. The array circuit substrate of claim 1, wherein the etching windows are separated from the adjacent non-stick test circuits by about 50 μm.

9. A wire bonding process, comprising:
providing an array substrate, which having a plurality of wire bonding pads, a plurality of plated wires and a plurality of non-stick test circuits, and each of the plated wires are connected one of the corresponding wire bonding pads to the adjacent non-stick test circuits, wherein at least one of the plated wires is a test wire;
forming a plurality of etching windows to cut the plated wires, expect the test wire;
bonding a first end of a first bonding wire to a first bonding pad of a chip; and
bonding a second end of the first bonding wire to a first wire bonding pad, which electrically connected to the test wire;
bonding a first end of a second bonding wire to a second bonding pad of the chip;
performing a non-stick test to check whether the first bonding wire and the second bonding wire are in good bonding condition or not, if yes, a current signal is received by a tester, if not, a current signal is not received by the tester or the received current signal is smaller than a predefined value;
bonding a second end of the second bonding wire to a second wire bonding pad, and cutting the second bonding wire out from a wire bonder;
performing the non-stick test to check whether the second bonding wire is connected to the second wire bonding pad or not, if yes, a current signal is not received by the tester, if not, a current signal is received by the tester; and
repeating the wire bonding steps and the non-stick test until the connection between the bonding pads and the wire bonding pads are completed.

10. The wire bonding process of claim 9, wherein the etching windows are formed by optical etching.

11. The wire bonding process of claim 9, wherein the etching windows are formed by wet etching or dry etching.

12. The wire bonding process of claim 9, wherein the width of the etching windows is about 100˜200 μm.

13. The wire bonding process of claim 9, wherein the etching windows are separated from the adjacent non-stick test circuits by about 50 μm.
